(19) United States
(12) Patent Application Publication
(10) Pub. No.: US 2009/0212287 A1
(43) Pub. Date: Aug. 27, 2009

(54) THIN FILM TRANSISTOR AND METHOD FOR FORMING THE SAME

(75) Inventors: Arokia Nathan, Cambridge (GB); Andrei Sazonov, Waterloo (CA); Mohammed Reza Esmaeili Rad, Waterloo (CA)

Correspondence Address: Altera Law Group, LLC, 220 S 6 St Suite 1700, Minneapolis, MN, 55402, US

(73) Assignee: Ignis Innovation Inc., Kitchener (CA)

(21) Appl. No.: 12/259,405

(22) Filed: Oct. 28, 2008

Related U.S. Application Data
(60) Provisional application No. 60/983,824, filed on Oct. 30, 2007.

(51) Int. Cl. H01L 29/786; H01L 21/336

(52) U.S. Cl. 257/57; 438/158; 257/E29.291; 257/E21.414

(57) ABSTRACT

A thin film transistor (TFT) and the method of forming the same is provided. The method of forming the TFT on a surface of a substrate, includes the steps of: forming a gate electrode; deposing a gate dielectric on the gate electrode; forming a nanocrystalline silicon (nc-Si) layer and an amorphous silicon (a-Si:H) layer above the gate dielectric, so that the thickness of the nc-Si layer is less than 30 nm thereby reducing off-current; and forming a source/drain electrode. The TFT includes: a gate electrode on a substrate, a gate dielectric on the gate electrode; a nc-Si layer having a thickness less than 30 nm, thereby reducing off-current; an a-Si:H layer; and a source/drain electrode.

### CROSS-REFERENCE TO RELATED APPLICATIONS

The present application claims priority to provisional application Ser. No. 60/983,824 filed on Oct. 30, 2007, and is incorporated by reference herein in its entirety.

### FIELD OF INVENTION

The invention relates to a semiconductor technology, and more specifically to a thin film transistor (TFT) and a method of forming the same for active matrix thing film electronics.

### BACKGROUND OF THE INVENTION

Current interest in active matrix pixilated arrays extends well beyond the ubiquitous active matrix liquid crystal display (AMLCD), that is routinely used as lap top and desk top screens, to several newly emerging and technologically important application areas. Notable examples include linear and area arrays for document scanning, digital copiers, and fax machines, bio-medical x-ray and optical imagers, radio-frequency interrogation tags, and non-destructive testing of material/structural integrity. More significantly, the TFT active matrix is emerging as a promising technology for back-plane electronics for a new generation of displays based on the organic light emitting diode (OLED) on both glass and flexible substrates.

In all of these applications, the basic unit in the active matrix is the pixel, which is accessed by a matrix of gate and data lines. FIGS. 1(a)-1(d) illustrate pixels 2, 4, 6, and 8 of varying integration complexity for four different application areas: (a) LCD, (b) passive pixel sensor (PPS), (c) active pixel sensor (APS) in imagers, and (d) OLED displays.

The basic pixel architecture in FIGS. 1 (a)-(d) is similar in topology: every pixel has a thin film transistor (TFT), which plays the role of a switching element; address lines 10 run vertically (Y) and are connected to the gate of the TFT switch; and data lines 12 run horizontally (X). In FIGS. 1(a)-1(d), “TFTn” (n=0, 1, 2, . . . ) represents a thin film transistor.

The operation of the pixels is generally quite similar also. In the case of displays, upon activation of the pixel via the address line 10, the data line 12 transfers charge (signal) to the pixel to set the voltage on the liquid crystal capacitor (Cpixel) (FIG. 1 (a)) or current through the OLED (FIG. 1 (d)). In the case of imagers, the opposite occurs. The charge (signal) on the photosensor (photodiode, MIS, or photo-TFT) is read out via the TFT switch to the data lines 12 (FIG. 1 (b)). Alternatively, the signal charge can be amplified for greater noise immunity using a source follower arrangement (FIG. 1(c)).

FIGS. 2-3 illustrate a process of forming a conventional TFT, i.e. a hydrogenated amorphous silicon (a-Si:H) TFT, which may be used in the circuits of FIGS. 1(a)-1(d). Referring to FIG. 2, a TFT includes a substrate 31, a gate electrode 32 formed by depositing and pattering and by lithography, a conductive material, a gate dielectric 33, an a-Si:H active layer 34, and passivation dielectric 35 layers subsequently formed on the gate electrode 32. The passivation nitride 35 is then patterned to open access points to the active layer 34. Referring to FIG. 3, extrinsic layer 36 and source/drain conductive layers 37 are subsequently deposited and patterned to complete the device fabrication and to enable the device connection to the outside.

An alternative TFT formation sequence, known as back channel etched process, can be used and is formed as follows: after formation of the gate electrode 32, the gate dielectric 33 and the a-Si:H active layer 34 and the extrinsic layer 36 are formed in one deposition cycle. Then, the extrinsic layer 36 is patterned to separate the source and drain regions, which follows by the source/drain conductive layer 37 formation and patterning and by the passivation dielectric 35 formation.

However, in this conventional TFT, the a-Si:H active layer 34 is not electrically stable, i.e. the threshold voltage of the TFT changes under applied gate voltage. For example, the threshold voltage of the TFT5 in FIG. 1(d) starts increasing when the voltage on its gate connected to storage capacitor is non-zero. This leads to a decrease in the driving current through the diode and, consequently, a decrease in the output light by the diode. The ultimate effect would be picture non-uniformity across the display screen. This effect becomes highly visible when the TFT has to operate for long time.

To avoid the issue of the threshold voltage shift, nanocrystalline silicon (nc-Si), also called microcrystalline silicon, has been used as the active layer as shown in FIG. 4. FIG. 4 illustrates the cross-section of a conventional nanocrystalline TFT. In this structure, the active layer is composed of a nc-Si 38 and the a-Si:H 34. The use of the nc-Si layer 38 alleviates the threshold voltage shift. However, according to the prior art, the interface between the nc-Si 38 and the gate dielectric 33 has to be treated by an oxygen-containing plasma, before forming the nc-Si 38 layer, in order to increase the crystalline volume fraction of the nc-Si and to form crystalline grains favorably. The oxygen-containing plasma uses gases such as N2O, NO, NO2, H2O2 which are not compatible with the standard mainstream TFT technology and leads to process complexity and cost.

A further drawback is that all these gases are considered greenhouse gases. In addition, according to the prior art, the thickness of the a-Si:H layer 34 is arbitrary and it is only used to reduce the device fabrication cost. However, the a-Si:H layer 34 has a strong bearing on the electrical performance of the TFT and, for example, the current provided by the TFT when it is on to drive the OLED pixel in FIG. 1(d) is affected by the thickness of the a-Si:H layer 34, i.e. decreases by increasing the a-Si:H thickness. On the other hand, without the a-Si:H layer 34, the off-current of the TFT increases by several orders of magnitude, leading to leakage of the stored charge on the storage capacitor through TFT1 in FIG. 1(b). As a result, a method compatible with the standard fabrication technology to produce a TFT with reduced threshold voltage shift and capable of meeting the driving current requirements, in both on- and off-state operation conditions, is highly demanded.

### SUMMARY OF THE INVENTION

It is an object of the invention to provide a TFT and a method of forming the TFT that obviates or mitigates at least one of the disadvantages of existing systems.

According to an aspect of the present invention there is provided a method of forming a thin film transistor on a surface of a substrate, includes the steps of: forming a gate electrode; deposing a gate dielectric on the gate electrode; forming a nanocrystalline silicon (nc-Si) layer and an amorphous silicon (a-Si:H) layer above the gate dielectric, so that the thickness of the nc-Si layer is less than 30 nm thereby reducing off-current; and forming a source/drain electrode.

According to another aspect of the present invention there is provided a TFT includes: a gate electrode on a substrate, a gate dielectric on the gate electrode; a nc-Si layer having a thickness less than 30 nm, thereby reducing off-current; an a-Si:H layer; and a source/drain electrode.

### BRIEF DESCRIPTION OF THE DRAWINGS

These and other features of the invention will become more apparent from the following description in which reference is made to the appended drawings wherein:

FIG. 1 (a) illustrates a pixel of a conventional Liquid Crystal Display (LCD);

FIG. 1 (b) illustrates a pixel of a conventional Passive Pixel Sensor (PPS);

FIG. 1 (c) illustrates a pixel of a conventional Active Pixel Sensor (APS);

FIG. 1 (d) illustrates a pixel of a conventional Organic Light Emitting Diode (OLED) display;

FIGS. 2-3 illustrate schematic cross sectional views of forming a conventional thin film transistor (TFT);

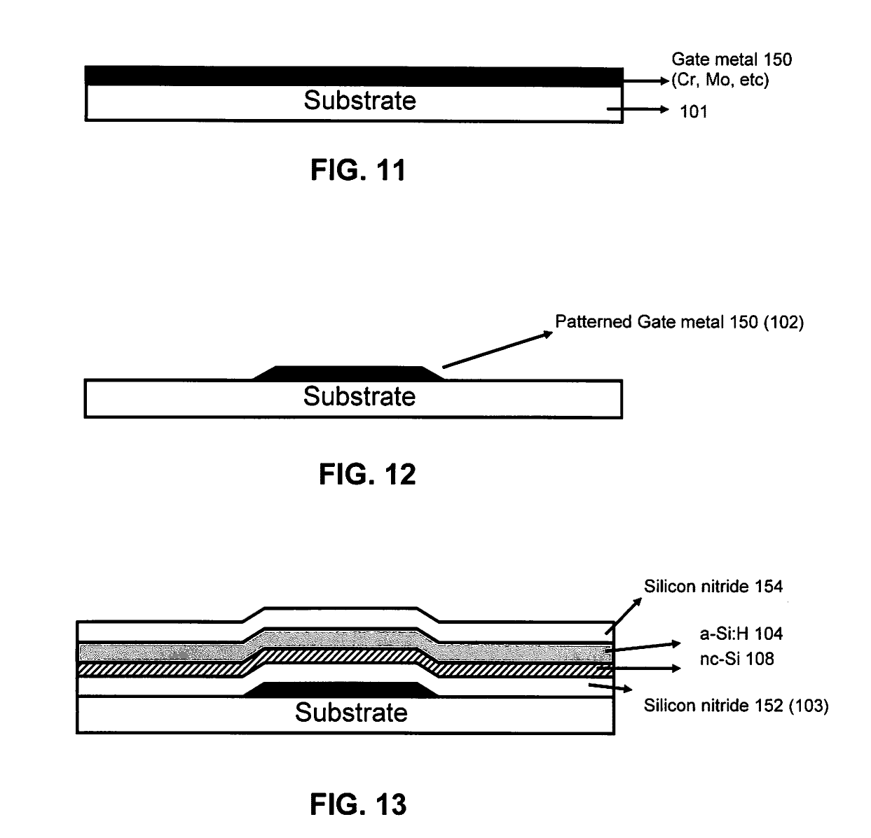

FIG. 4 illustrates a schematic cross sectional view of another conventional TFT;

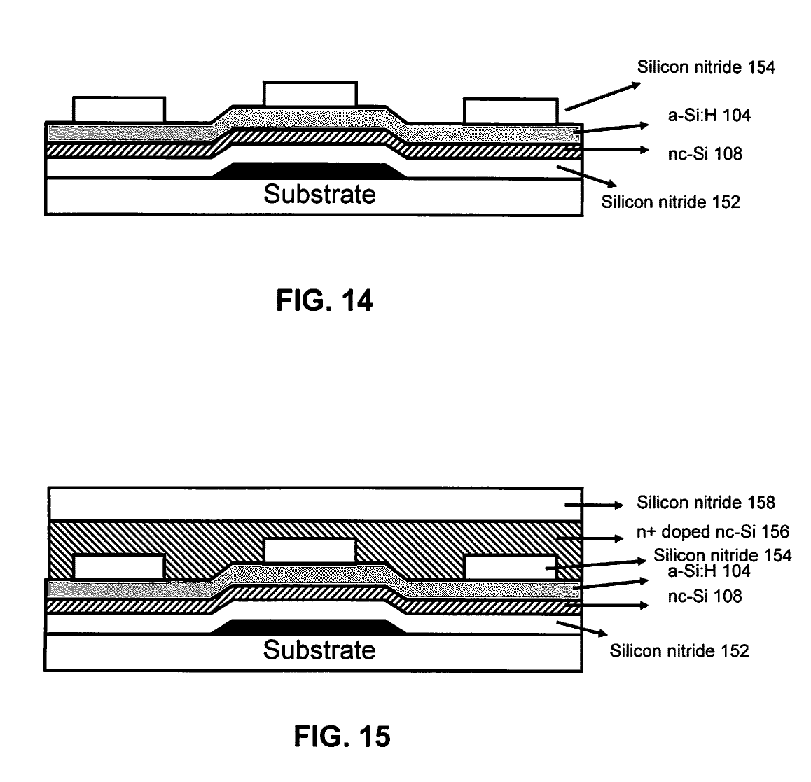

FIGS. 5-7 illustrate schematic cross sectional views of forming a TFT in accordance with an embodiment of the present invention;

FIGS. 8-10 illustrate schematic cross sectional views of forming a TFT in accordance with another embodiment of the present invention;

FIGS. 11-18 illustrate an example of the process of forming a TFT in accordance with an embodiment of the present invention;

FIGS. 19-24 illustrate another example of the process of forming a TFT in accordance with an embodiment of the present invention;

FIGS. 25(a) and 25(b) are graphs showing transfer characteristics of TFTs with non-optimized nc-Si channel thickness; and

FIGS. 26(a) and 26(b) are graphs showing transfer (a) and output (b) characteristics of TFT with optimized thickness layers in accordance with an embodiment of the present invention.

### DETAILED DESCRIPTION

Embodiments of the present invention describe a TFT that includes a patterned gate electrode on a substrate, a gate dielectric formed on the gate electrode, a nc-Si layer, an a-Si:H layer (cap layer), and a passivation dielectric or silicon nitride layer.

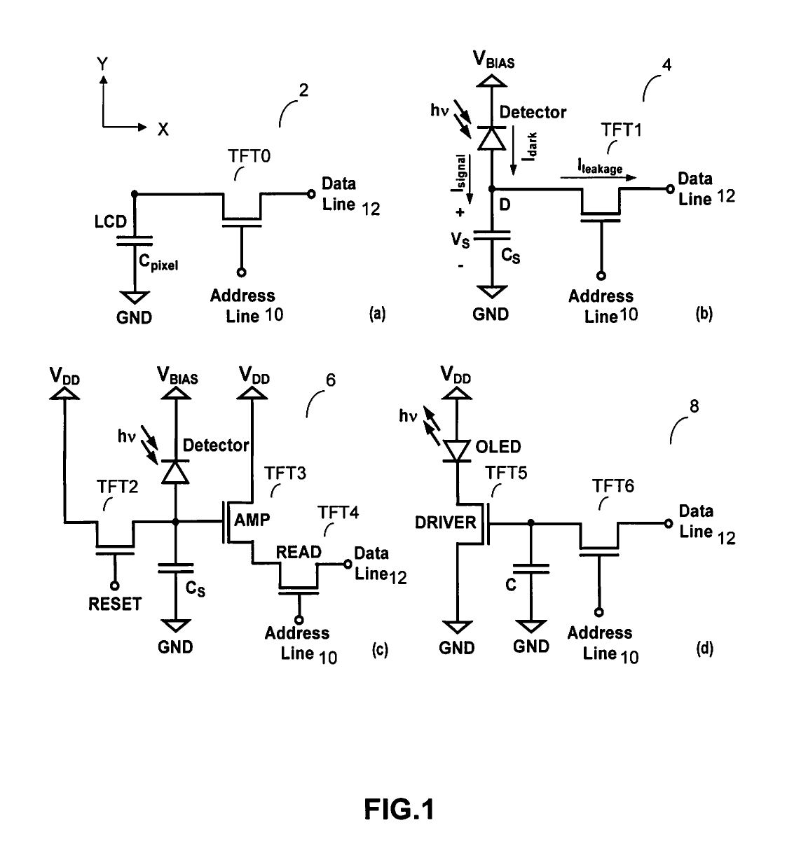

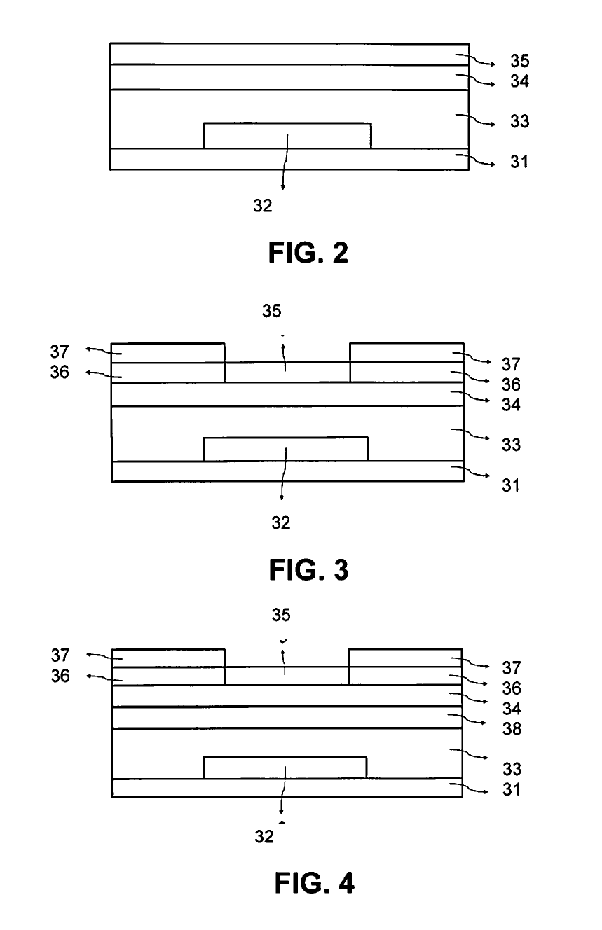

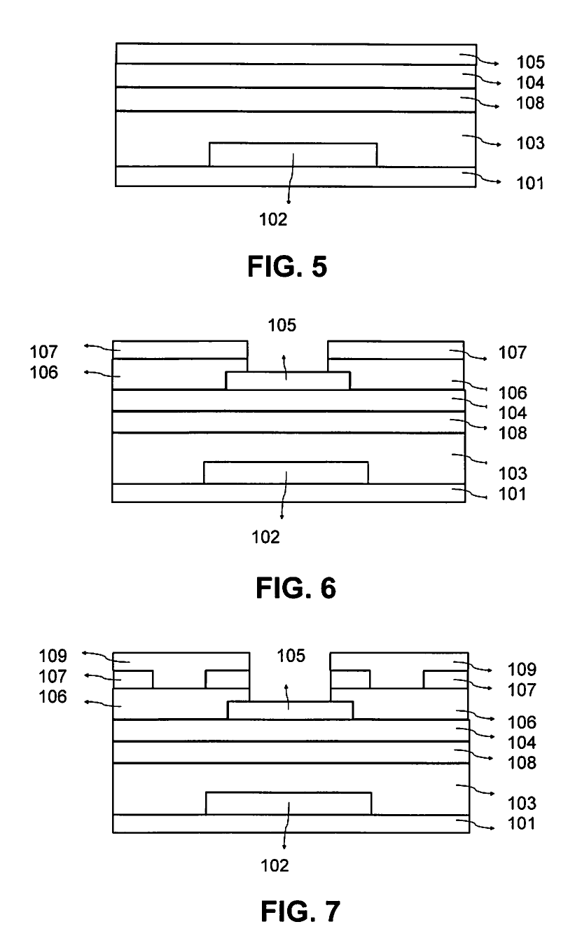

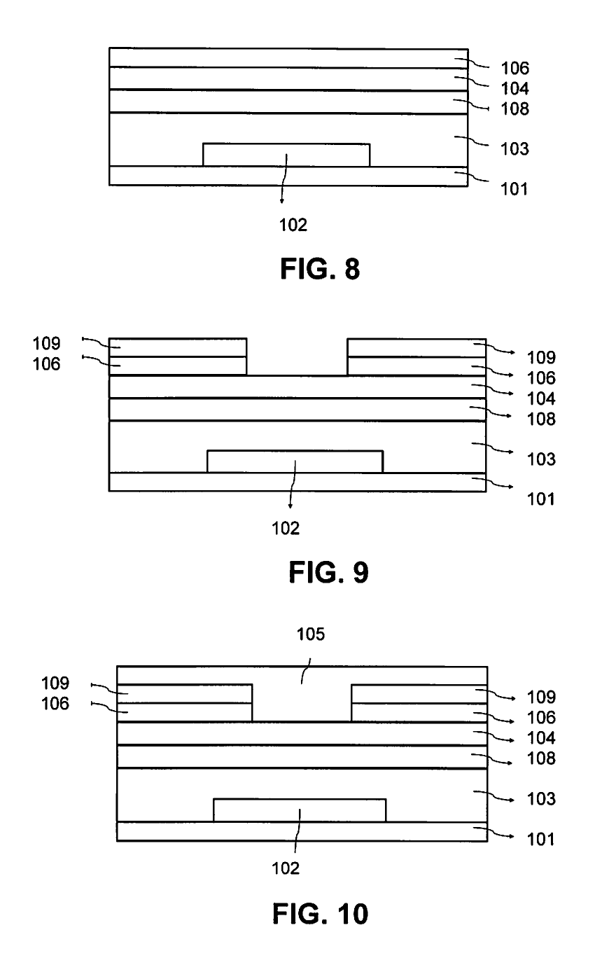

The TFT in accordance with the embodiments of the present invention may be used for displays and imagers, including those of FIGS. 1(a)-(d). The TFT in accordance with the embodiments of the present invention may be used for active matrix flat panel electronics.

As described in detail below, the method of forming the nc-Si layer on the gate dielectric is fully compatible with the standard fabrication processes while the nanocrystals form at the interface with the gate dielectric which results in reduced threshold voltage shift of the TFT. Furthermore, the a-Si:H and the nc-Si layer with a proper thickness described below minimizes the TFT source-drain leakage current (off-current) without compromising the TFT drive current in the on state. As a result of these improvements, active matrix thin film electronics, such as OLED displays, can be produced with higher picture quality, longer lifetime, and at reduced cost.

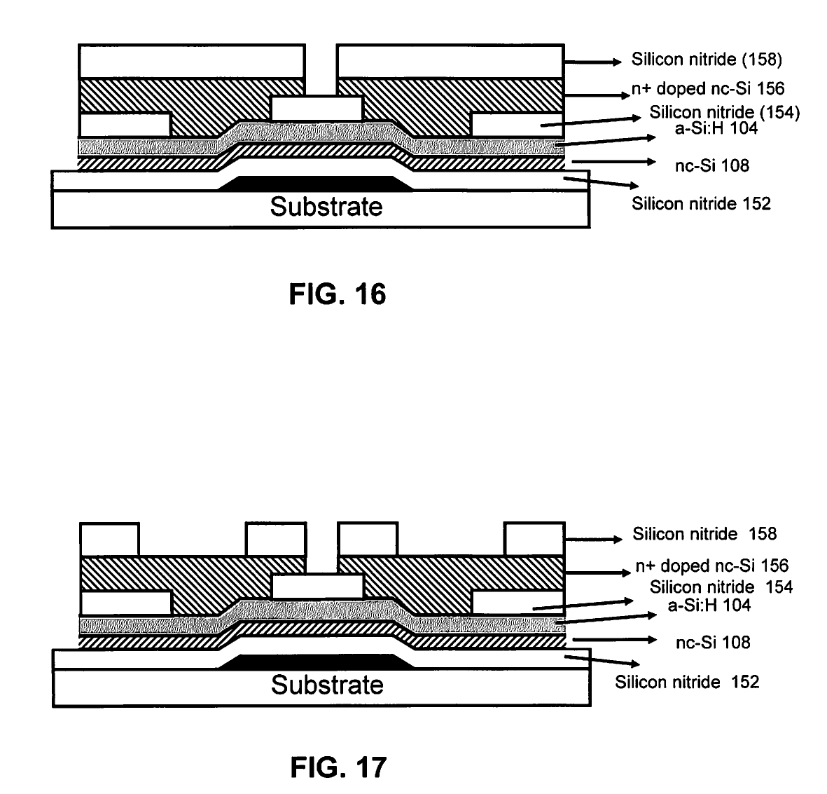

In the description below, relative terms, such as “top”, “bottom”, “above”, “on”, may be used herein to describe one element's relationship to another element as shown in the drawings. It will be appreciated by one of ordinary skill in that art that that the relative terms may encompass different orientations of the components, in addition to the orientation shown in the drawings. In FIGS. 5-24, components/elements/layers illustrated in the drawings are schematic in nature and their shapes are not intended to illustrate their precise shapes.

FIGS. 5-7 illustrate the formation sequence of a TFT in accordance with an embodiment of the present invention. The TFT of FIGS. 5-7 contains a substrate 101, a gate electrode 102, a gate dielectric 103, an a-Si:H active layer 104, a passivation dielectric layer 105, and an nc-Si layer 108. The nc-Si layer 108 is capped with the a-Si:H layer 104.

The substrate 101 is, for example, but not limited to, a glass or a plastic. The gate electrode 102 is formed of a conductive material, for example, but not limited to, aluminum, chromium, molybdenum, etc, on the substrate 101. The gate dielectric 103 may be, for example, but not limited to, silicon oxide, silicon nitride, or silicon oxynitride.

The gate electrode 102 is disposed on the substrate 101. Then, the gate dielectric 103 is formed on the gate electrode 102. Before forming the nc-Si layer 108, the hydrogen plasma treatment is performed on the gate dielectric 103. Following the hydrogen plasma treatment, the nc-Si layer 108, the a-Si:H layer 104 and the passivation dielectric layer 105 are deposited on the gate dielectric 103. These layers are deposited, for example, by plasma enhanced chemical vapor deposition (PECVD) method, and they may be formed, for example, but not limited to, either in a single PECVD chamber sequentially or in several chambers, like in cluster tools, dedicated for different type of layers.

Favorable formation of crystalline grains at the interface with the gate dielectric is achieved by using the hydrogen plasma, which is common (standard) in silicon TFT technology and is not a greenhouse gas. The conditions of the hydrogen plasma treatment may vary depending on specific equipment or substrates used, which would be well understood by one of ordinary skill in the art.

The PECVD method is the standard deposition technique for the gate dielectric and the channel layer in the industry, and the PECVD method and its condition could be well appreciated by one of ordinary skill in the art. The existing industrial plants for the PECVD can fabricate the TFT in accordance with the embodiments of the present invention without any changes in equipment. In another example, methods other than the PECVD may be applied to achieve the same result as that of the PECVD.

As shown in FIG. 6, the TFT fabrication sequence continues with patterning the passivation dielectric 105 by lithography and forming another two layers; an extrinsic layer 106 and a dielectric layer 107. Following this patterning, a portion of the dielectric layer 107 is removed by lithography, and a metal layer is subsequently deposited and patterned to form the TFT source/drain electrodes 109, and the TFT production is finished. The TFT fabrication sequence after forming the passivation dielectric 105 would be well understood by one of ordinary skill in the art.

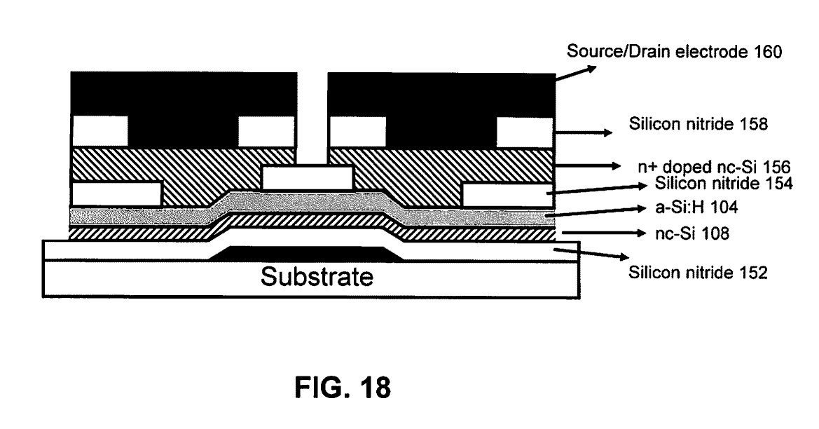

FIGS. 8-10 illustrate the formation sequence of a TFT in accordance with another embodiment of the present invention. In FIGS. 8-10, the TFT formation sequence is based on a back channel etched process. As shown in FIG. 8, after formation of the gate electrode 102, the gate dielectric 103, the nc-Si layer 108, the a-Si:H active layer 104, and the extrinsic layer 106 are formed once.

Then, as shown in FIG. 9, the extrinsic layer 106 is patterned to separate the source and drain regions, which follows by the source/drain conductive layer 109 formation and patterning. Finally, the passivation dielectric 105 is formed to passivate the active layer, as shown in FIG. 10.

In one example, the hydrogen plasma treatment and PECVD method are applied to form the TFT of FIGS. 8-10. The sequence of forming the layers 106, 109 and 105 in FIGS. 8-10 would be well understood by one of ordinary skill in the art. In another example, methods other than the PECVD may be applied.

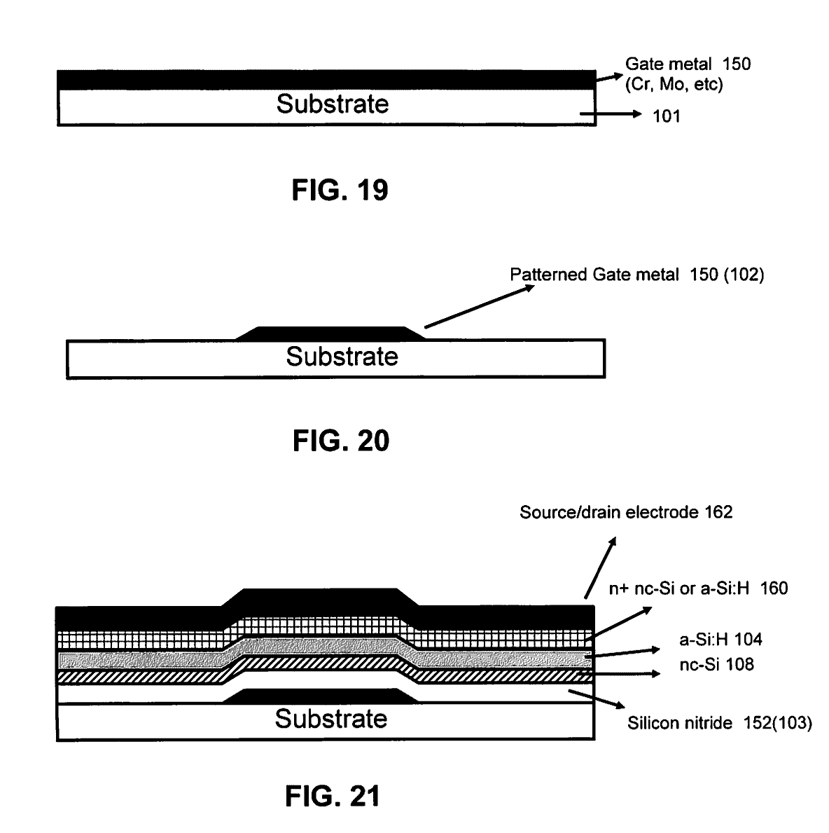

FIGS. 11-18 illustrate an example of the process of forming a TFT in accordance with an embodiment of the present invention. Referring to FIGS. 11-18, the gate material 150 is disposed on the substrate 101, and then the gate electrode 102 is formed. Silicon nitride layer 152 (gate insulator), nc-Si layer 108, a-Si:H layer 104, and another silicon nitride layer 154 are disposed. The silicon nitride 154 is patterned. Then n+ doped nc-Si layer 156 and silicon nitride layer 158 are disposed. A portion of the layers 154, 156, 102, and 108 is removed by etching process. Then a source/drain electrode 160 is formed.

In one example, the hydrogen plasma treatment is applied to form the TFT of FIGS. 11-18, immediately prior to the nc-Si film 108 deposition. In one example, the PECVD process is applied to form the TFT of FIGS. 11-18, more specifically, to deposit silicon nitride 152 (103), 154, and 158, nc-Si 108, a-Si:H 104, and n+ doped nc-Si 156. In another example, methods other than the PECVD may be applied.

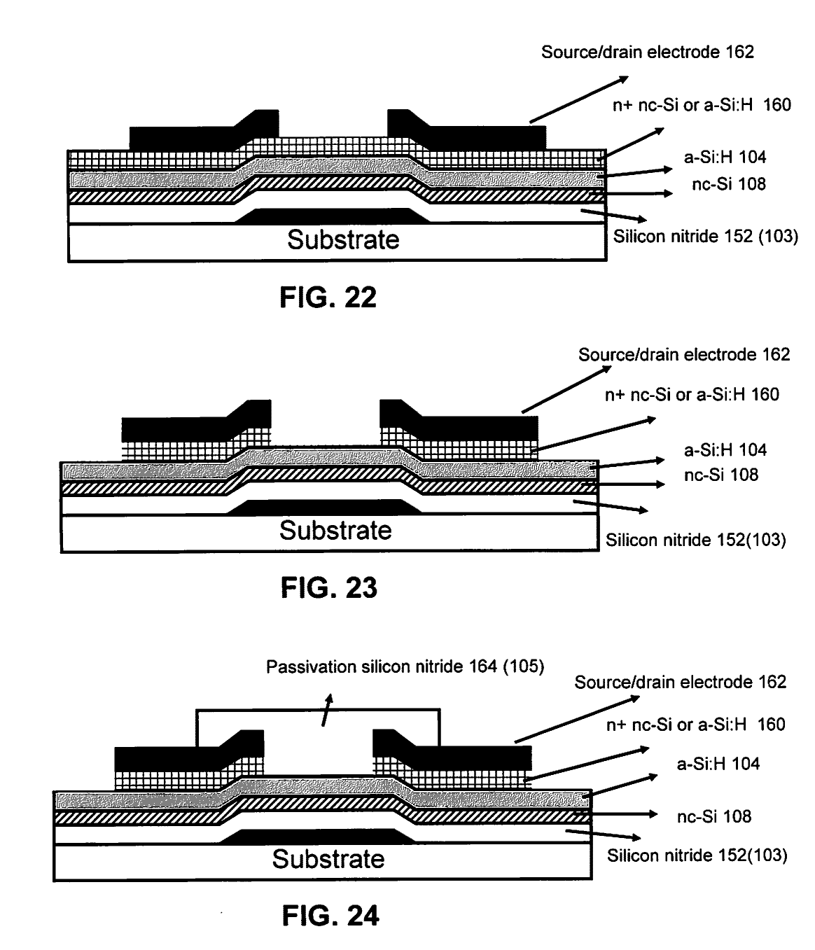

FIGS. 19-24 illustrate another example of the process of forming a TFT in accordance with the embodiment of the present invention. Referring to FIGS. 19-24, the gate material 150 is disposed on the substrate 101, and then the gate electrode 102 is formed. Silicon nitride layer 152 (gate insulator), nc-Si layer 108, a-Si:H layer 104, and n+ doped nc-Si or a-Si:H layer 160 are disposed. Source/drain electrode 162 is formed, and a portion of n+ doped nc-Si or a-Si:H layer 160 is removed by etching process. Then a passivation silicon nitride 164 (105) is formed.

In one example, the hydrogen plasma treatment is applied to form the TFT of FIGS. 19-24, prior to the nc-Si film 108 deposition. In one example, the PECVD process is applied to form the TFT of FIGS. 19-24. In another example, methods other than the PECVD may be applied.

Referring to FIGS. 5-24, in one example, the thickness of the nc-Si layer 108 is under 30 nm. The nc-Si layer thickness is kept below 30 nm to minimize the leakage current (off-current) and to minimize the deposition time. This thickness range of the nc-Si layer is applied to any type or any size of TFTs.

If nc-Si layer is thinner than 10 nm, incomplete coverage of underlying gate dielectric may occur, i.e., the channel layer may be discontinuous, hence no electrical conduction may occur in the TFT. Thus, in another example, the thickness of the nc-Si layer is in the range of 10-30 nm. This thickness range of the nc-Si layer is applied to any type or any size of TFTs.

In one example, the thickness of the a-Si:H layer 104 is in the range of 10-50 nm. This thickness range 10-50 nm for the a-Si:H layer 104 is applied to any type or any size of TFTs. The thickness range of the a-Si:H layer 104 is related to the thickness range 10-30 nm of the nc-Si layer. The thickness range 10-50 nm for the a-Si:H layer 104 and the thickness range 10-30 nm for the nc-Si layer ensure that the TFT leakage current (off-current) is low, while the TFT on current is high and not undermined by the undesirable effect of a thick a-Si:H layer.

In one example, in order to be compatible with existing a-Si:H TFT fabrication process (in terms of the channel layer thickness), the combined thickness of the a-Si:H layer 104 and the nc-Si layer 108 is kept not to exceed 100 nm, which is maximum channel layer thickness in back channel etched a-Si:H TFTs, and not to be below 50 nm, which is minimum channel layer thickness in conventional TFT. This combined thickness range is chosen because: i) if a-Si:H layer is thinner than 10 nm, incomplete coverage of underlying nc-Si may occur, i.e., the channel layer may be discontinuous, hence high leakage current may occur in the TFT; ii) a-Si:H layer thickness is kept below 50 nm to keep the entire channel layer thickness below 100 nm. The combined thickness range of a-Si:H layer and nc-Si layer ensures low threshold voltage shift and low off-current without reducing on-current.

In FIGS. 5-24, the PECVD parameters are adjusted so that the nanocrystals form favorably from the gate dielectric interface and the so-called incubation layer does not grow at the interface to obtain an electrically stable active layer. The adjustable PECVD parameters include, for example, but not limited to, the power density, the gas pressure in the deposition chamber, the substrate temperature, and the source gas flow rates.

In one embodiment, among the PECVD parameters, the power density is around 10 mW/cm2, the chamber pressure is around 1 Torr, and the ratio of hydrogen to silane gas flow rates is around 100. The substrate temperature is in the range of 200-350° C. In another example, the formation of the TFTF may be used in any application which permits a fabrication budget of, for example but not limited to, 300° C. or below. In a further example, the temperature may be around or below 150° C. to make it plastic compatible. These requirements are applied to any type or any size of TFTs.

The numbers (in particular, 200-350° C.) are determined experimentally and are known in the art; any variations within these ranges may be applicable and do not result in significant changes of TFT performance.

In contrast to the prior art, the TFT formation according to the embodiments of the present invention does not use oxygen-containing gases to treat the gate dielectric layer 103. Instead, as described above, before forming the nc-Si layer 108, the hydrogen plasma treatment is performed on the gate dielectric 103. This is fully compatible with the standard fabrication processes, as hydrogen is also used as one of the input gases to form the nc-Si layer 108 by PECVD.

Therefore, the formation procedure and parameters given above can be used to make a TFT that can offer an acceptable current level in both on and off conditions and, more significantly, can offer a reduced threshold voltage shift. As a result, high performance organic light emitting diode displays with quality picture and longer lifetime can be manufactured, using well-established and conventional facilities at low cost.

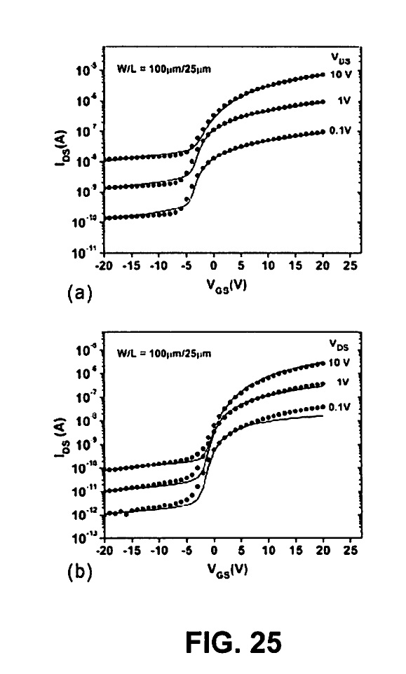

FIGS. 25(a) and 25(b) are graphs showing transfer characteristics of TFT with non-optimized nc-Si channel thickness. In FIG. 25(a), TFT having an all nc-Si channel layer of thickness 65 nm was used. In FIG. 25(b), TFT having 65 nm nc-Si channel layer capped with 100 nm a-Si:H was used. In FIGS. 25(a) and 25(b), dots represent the results of the experiment, and lines represent the computation result. The aspect ratio W/L is 100 μm/25 μm.

Introduction of a-Si:H cap reduces the leakage current by 2 orders of magnitude compared to single channel layer nc-Si TFT (e.g., VDS=1V, the off-currents are 2 nA and 10 pA. However, the a-Si:H layer increases the source/drain series resistance which reduces the on current, and the nc-Si layer has a high conductivity which increases the leakage current (off-current), since the nc-Si channel and a-Si:H cap thicknesses are not optimized (too thick).

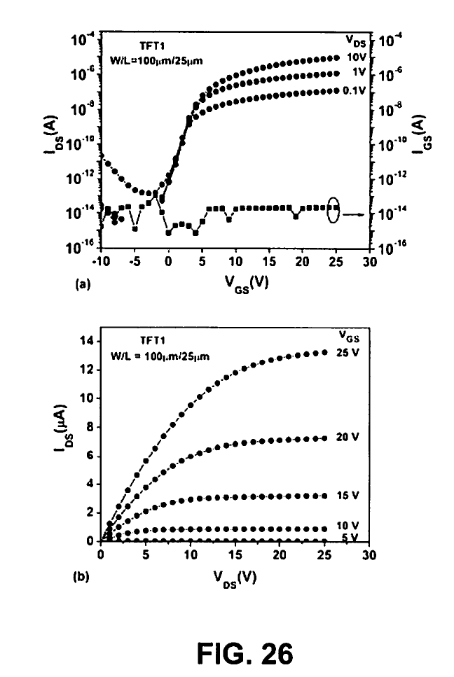

FIGS. 26(a) and 26(b) are graphs showing transfer (a) and output (b) characteristics of TFT with optimized thickness layers in accordance with an embodiment of the present invention. In FIGS. 26(a) and 26(b), TFT having 15 nm nc-Si channel layer capped with 35 nm a-Si:H was used (e.g., 108 and 104 in the drawings). The aspect ratio W/L is 100 μm/25 μm. The leakage current is reduced 1 to 3 orders of magnitude compared to those of FIGS. 25(a) and 25(b), (e.g., (2-3)×10⁻¹³ A at VDS=10V) and is now of the same magnitude as state of art a-Si:H TFTs. “Analysis of the off current in nanocrystalline silicon bottom-gate thin-film transistors”, Journal of Applied Physics 103, 074502 (2008), by Mohammad R. Esmaeili-Rad, Andrei Sazonov, and Arokia Nathan, shows the analysis of the optimized thickness, which is incorporated herewith by reference.

One or more currently preferred embodiments have been described by way of example. It will be apparent to persons skilled in the art that a number of variations and modifications can be made without departing from the scope of the invention as defined in the claims.

What is claimed is:

1. A method of forming a thin film transistor on a surface of a substrate, comprising the steps of:
forming a gate electrode;
deposing a gate dielectric on the gate electrode;
forming a nanocrystalline silicon (nc-Si) layer and an amorphous silicon (a-Si:H) layer above the gate dielectric, so that the thickness of the nc-Si layer is less than 30 nm thereby reducing off-current; and
forming a source/drain electrode.

2. A method as claimed in claim 1, wherein the thickness of the nc-Si layer is in the range of about 10 nm-30 nm.

3. A method as claimed in claim 1, wherein the thickness of the a-Si:H layer is less than about 50 nm, thereby reducing off-current without reducing on-current.

4. A method as claimed in claim 3, wherein the thickness of the a-Si:H layer is in the range of about 10 nm-50 nm.

5. A method as claimed in claim 1, wherein the combined thickness of the a-Si:H layer and the nc-Si layer is less than about 100 nm, thereby reducing the off-current without reducing on-current.

6. A method as claimed in claim 5, wherein the combined thickness of the a-Si:H layer and the nc-Si layer is in the range of about 50 nm-100 nm.

7. A method as claimed in claim 1, comprising:
forming a passivation layer.

8. A method as claimed in claim 1, comprising prior to the step of forming a source/drain electrode:
forming a first silicon nitride layer; and
forming a n+ doped nc-Si layer or a-Si:H layer.

9. A method as claimed in claim 1, wherein the thin film transistor is formed by back channel etched process.

10. A method as claimed in claim 1, comprising:
performing a hydrogen plasma treatment on the gate dielectric.

11. A method as claimed in claim 1, wherein the step of forming comprises:
performing enhanced chemical vapor deposition (PECVD) process.

12. A method as claimed in claim 11, wherein the step of performing PECVD process comprises setting a power density around 10 mW/cm².

13. A method as claimed in claim 11, wherein in the step of performing PECVD process comprises setting a chamber pressure is around 1 Torr.

14. A method as claimed in claim 11, wherein in the step of performing PECVD process comprises setting the ratio of hydrogen to silane gas flow rates around 100.

15. A method as claimed in claim 11, wherein in the step of performing PECVD process comprises setting a substrate temperature in the range of around 200-350° C.

16. A method as claimed in claim 11, wherein in the step of performing PECVD process comprises setting a temperature around or below 150° C.

17. A thin film transistor comprising:
a gate electrode on a substrate,
a gate dielectric on the gate electrode;
a nc-Si layer having a thickness less than 30 nm, thereby reducing off-current;
an a-Si:H layer; and
a source/drain electrode.

18. A thin film transistor as claimed in claim 17, wherein the thickness of the nc-Si layer is in the range of about 10 nm-30 nm.

19. A thin film transistor as claimed in claim 17, wherein the thickness of the a-Si:H layer is less than about 50 nm, thereby reducing off-current without reducing on-current.

20. A thin film transistor as claimed in claim 19, wherein the thickness of the a-Si:H layer is in the range of about 10 nm-50 nm.

21. A thin film transistor as claimed in claim 17, wherein the combined thickness of the a-Si:H layer and the nc-Si layer is less than about 100 nm, thereby reducing the off-current without reducing on-current.

22. A thin film transistor as claimed in claim 21, wherein the combined thickness of the a-Si:H layer and the nc-Si layer is in the range of about 50 nm-100 nm.
